(19) United States
(12) Patent Application Publication
(10) Pub. No.: US 2011/0057329 A1
(43) Pub. Date: Mar. 10, 2011

(54) ELECTRONIC DEVICE AND MANUFACTURING METHOD OF ELECTRONIC DEVICE

(75) Inventor: Yoshitaka USHIYAMA, Kanagawa (JP)

(73) Assignee: RENESAS ELECTRONICS CORPORATION, Kawasaki-shi (JP)

(21) Appl. No.: 12/876,361

(22) Filed: Sep. 7, 2010

(30) Foreign Application Priority Data
Sep. 8, 2009 (JP) 2009-206924

(51) Int. Cl. H01L 23/28; H01L 21/56

(52) U.S. Cl. 257/779; 438/126; 257/E21.502; 257/E23.116

(57) ABSTRACT

It is desired to provide an electronic device which can be easily taken out of a mold after resin sealing processing. The electronic device includes: an insulating layer; a wiring layer formed on a surface of the insulating layer; a first solder resist formed to cover the insulating layer and the wiring layer and including a particle of a first elastomer; and a second solder resist formed to cover a surface of the first solder resist. A surface of the second solder resist has smaller adhesive strength than the surface of the second solder resist at a glass transition point of the first elastomer.

### INCORPORATION BY REFERENCE

This patent application is based on Japanese Patent Application No. 2009-206924. The disclosure of the Japanese Patent Application is incorporated herein by reference.

### BACKGROUND OF THE INVENTION

1. Field of the Invention

The present invention relates to an electronic device, and particularly to a solder resist of a wiring substrate.

2. Description of Related Art

In order to address an increase in the number of pins and signal transmission at higher speed, packages having area array-type terminals such as the BGA (Ball Grid Array) and the LGA (Land Grid Array) have been widely adopted for a semiconductor package. A manufacturing process of the area array-type semiconductor package includes a resin sealing step for protecting a semiconductor element. The resin sealing step includes steps of: enclosing a wiring substrate (package substrate) that mounts a semiconductor element connected by means of a wire bonding connection or a flip chip connection thereon with molds; filling sealing resin liquefied at a high temperature into a cavity of the molds; and curing the filled sealing resin and taking a semiconductor device (semiconductor package) with the cured resin out of the molds. In the step of taking the semiconductor device out of the molds, various approaches have been considered to improve lowering of productivity due to adhesion of the semiconductor device to the molds.

A technique related to the step of taking a semiconductor device out of molds is disclosed in Japanese Patent Application Publication JP2002-166449A (which is referred to as Patent Document 1). A resin molding device disclosed in Patent Document 1 fills a resin into a cavity to perform resin molding and then, projects an ejector pin, to open the mold while releasing a molded piece from the cavity. Further, the resin molding device is provided with air suction means adapted to air-suck the molded piece onto a parting surface of the mold at mold opening. Such a resin molding device enables an automatic and smooth resin molding operation.

### SUMMARY

A solder resist layer having insulating properties is formed on a surface of a wiring substrate (package substrate, mounting board). The solder resist layer is formed for protecting a wiring pattern of the wiring substrate against external influences such as dusts and moisture and preventing solder from adhering to an unnecessary portion which may cause short-circuit. Further, the solder resist layer has an ability to bear a strain caused by thermal deformation. Especially when the solder resist layer is located at a connection part between a wiring substrate (package substrate) and a semiconductor element, the solder resist layer must have an ability to bear a strain caused by thermal deformation of the wiring substrate (package substrate) and the semiconductor element in the resin sealing step. Thus, the solder resist contains elastomer for relaxing an internal stress.

However, as a result of elaborate examination, the present inventor found a problem that, in addition to the difficulty of removing (demolding) the base material of the sealing resin from the mold caused by its adhesion, the elastomer contained in the solder resist becomes softened and easily adheres to the molds due to heat generated in the resin sealing step, thereby making removal of the molded semiconductor device from the mold more difficult.

According to an aspect of the present invention, an electronic device includes: an insulating layer; a wiring layer formed on a surface of the insulating layer; a first solder resist formed to cover the insulating layer and the wiring layer and including a particle of a first elastomer; and a second solder resist formed to cover a surface of the first solder resist. The surface of the second solder resist has smaller adhesive strength than the surface of the second solder resist at a glass transition point of the first elastomer.

In the electronic device of the present invention, since the solder resist is hard to adhere to a mold even when heat is applied, the electronic device can be easily taken out of the mold in the resin sealing step.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view of a semiconductor device 1 according to the present invention;

FIG. 2 is a sectional view showing a state in which a cavity formed by a mold 41 and a mold 42 is filled with a sealing resin 30 in a resin sealing step of the semiconductor device 1 of the present invention;

FIG. 3 is a partial sectional view of a wiring substrate 10 shown in FIG. 1 and FIG. 2;

FIG. 4 is an enlarged view of the portion A shown in FIG. 3;

FIG. 5 is a sectional view showing a state in which the wiring substrate 10 in FIG. 4 is in contact with the mold 41 in the resin sealing step;

FIG. 6 is a flow chart showing a method of manufacturing the wiring substrate 10 according to a first embodiment of the present invention;

FIG. 7 is a partial sectional view showing the wiring substrate 10 according to a second embodiment of the present invention;

FIG. 8 is a sectional view showing a state in which the wiring substrate 10 shown in FIG. 7 is in contact with the mold 41 in the resin sealing step;

FIG. 9 is a partial sectional view showing the wiring substrate 10 according to a third embodiment of the present invention;

FIG. 10 is an enlarged view of the portion B shown in FIG. 9;

FIG. 11 is a flow chart showing a method of manufacturing the wiring substrate 10 according to the third embodiment of the present invention;

FIG. 12 is a sectional view of a semiconductor device 100 according to a fourth embodiment; and

FIG. 13 is a partial enlarged view of a mounting board 110 shown in FIG. 12.

### DESCRIPTION OF THE PREFERRED EMBODIMENTS

An electronic device according to some exemplary embodiments of the present invention will be described referring to the accompanying drawings. The electronic device in the described embodiments represents a wiring substrate (package substrate, mounting board) or a semiconductor device in which a semiconductor element is mounted on the wiring substrate (package substrate, mounting board).

### First Embodiment

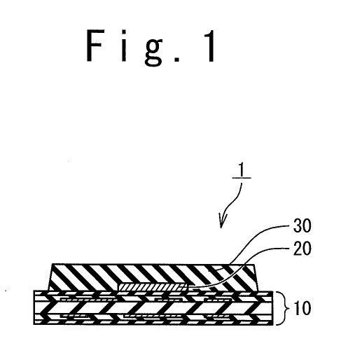

A first embodiment of the present invention will be described. FIG. 1 is a sectional view of the semiconductor device 1 according to the present embodiment. Referring to FIG. 1, the semiconductor device 1 includes a wiring substrate 10, a semiconductor element 20 and a sealing resin 30.

The wiring substrate 10 is an area array-type package substrate and connects the semiconductor element 20 to a mounting board (not shown). The semiconductor element 20 has a wiring for performing various functions thereon and is connected to the wiring substrate 10. Examples of a method of connecting the semiconductor element 20 to the wiring substrate 10 include wire bonding (not shown) and flip chip connection (not shown). The sealing resin 30 covers the semiconductor element 20 for protection.

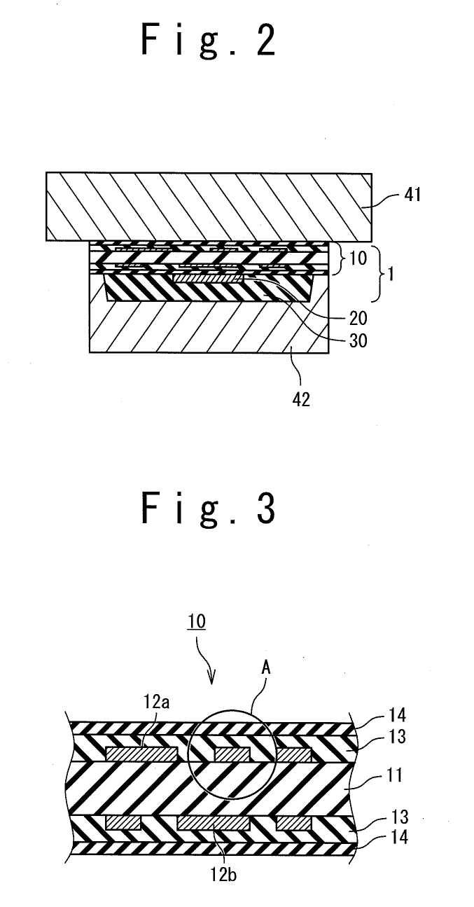

FIG. 2 is a sectional view showing a state in which a cavity formed by a mold 41 and a mold 42 is filled with the sealing resin 30 in a resin sealing step of the semiconductor device 1 of the present embodiment. Referring to FIG. 2, the resin sealing step will be described. The mold 41 and the mold 42 enclose the wiring substrate 10 on which the semiconductor element 20 is mounted to form the cavity into which the sealing resin 30 is filled. The sealing resin 30 in the form of high-temperature liquid is filled into the cavity formed by the mold 41 and the mold 42. The sealing resin 30 is not necessarily in the liquid form and may be in any state as long as it has fluidity (for example, in a gum state). Hereinafter, the liquid sealing resin 30 will be described. When the mold 41 and the mold 42 are heated to about 150 to 200° C., the sealing resin 30 filled into the cavity becomes cured (FIG. 2). The semiconductor device 1 including the cured sealing resin 30 is taken out of the mold 41 and the mold 42.

In a step of taking the semiconductor device 1 out of the mold 41 and the mold 42, disadvantageously, it is hard to strip the wiring substrate 10 away from the mold 41 and the mold 42. However, because the wiring substrate 10 of the present embodiment is hard to adhere to the mold 41 and the mold 42 as described later, the semiconductor device 1 can be easily taken out. The sealing resin 30 can be removed from the mold 41 and the mold 42 according to any of well known techniques.

Details of the wiring substrate 10 will be described below. Although the wiring substrate 10 is arranged to the molds 41, 42 so that the semiconductor element 20 is located beneath in FIG. 2, the molds 41, 42 and the wiring substrate 10 may be arranged upside down. That is, it is possible to mount the wiring substrate 10 on the underlying mold 41, dispose the semiconductor element 20 thereon and cover the semiconductor element 20 with the mold 42. The sealing resin 30 is filled into a cavity between the semiconductor element 20 and the mold 42 and then cured.

FIG. 3 is a partial sectional view of the wiring substrate 10 shown in FIG. 1 and FIG. 2. Referring to FIG. 3, the wiring substrate 10 according to the first embodiment of the present embodiment includes an insulating layer 11, a wiring layer 12a, a wiring layer 12b, a first solder resist 13 and a second solder resist 14. In the wiring substrate 10, the first solder resist 13 and the second solder resist 14 may be formed on a multi-layer substrate obtained by laminating one or more insulating layers and one or more wiring layers on the wiring layer 12a or the wiring layer 12b. Alternatively, the first solder resist 13 and the second solder resist 14 may be formed on the wiring substrate in which the wiring layer is formed on only one surface of the insulating layer. Parts of the first solder resist 13 and the second solder resist 14 are opened to expose parts of the wiring layers 12a, 12b to form electrode pads (not shown). A wire is wire bonding connected or a solder ball is flip chip connected to each of the electrode pads on one wiring layer's side to which the semiconductor element 20 is connected. An external terminal such as a solder ball is connected to each of the electrode pads on the other wiring layer's side.

The insulating layer 11 is a base member on which the wiring layer 12a and the wiring layer 12b are formed and blocks electrical conduction to the wiring layer 12a and the wiring layer 12b. The insulating layer 11 can be formed of a glass epoxy resin substrate obtained by impregnating a cloth woven from glass fibers with epoxy resin, a glass composite substrate obtained by impregnating glass fibers formed into a mat shape obtained by trimming the glass fibers with epoxy resin or the like according to well known techniques. A wiring layer (not shown) other than the wiring layer 12a and the wiring layer 12b may be formed on the insulating layer 11. A through hole penetrating the insulating layer 11 may be formed to connect predetermined wirings included in the wiring layer 12a and the wiring layer 12b to each other.

The wiring layer 12a is a leading wire formed on the insulating layer 11 with a predetermined pattern. The wiring layer 12b is a leading wire formed on the side of the insulating layer 11 opposite to the side on which the wiring layer 12a is formed with a predetermined pattern. The wiring layer 12a and the wiring layer 12b can be formed according to any of well known techniques. The thickness of each of the wiring layer 12a and the wiring layer 12b is, for example, in the range of 10 to 35 μm.

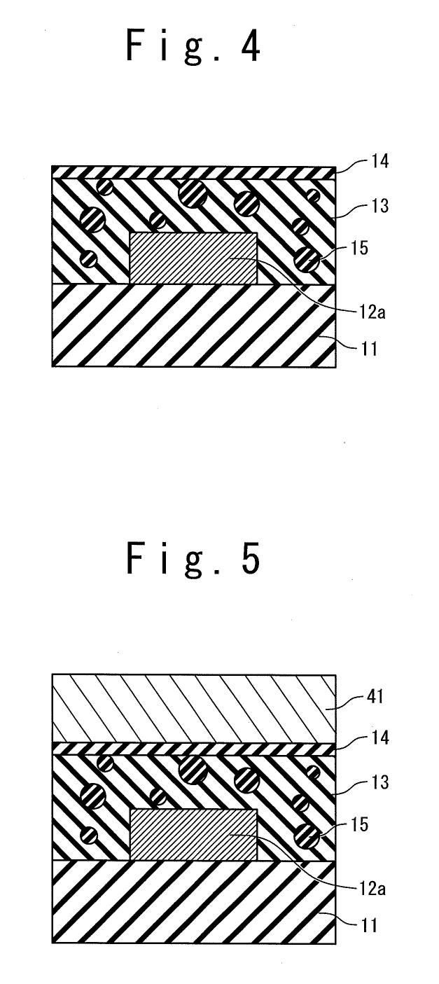

Details of the first solder resist 13 and the second solder resist 14 will be described. FIG. 4 is an enlarged view of the portion A shown in FIG. 3. The first solder resist 13 is an insulating film for protecting the wiring layer 12a and the wiring layer 12b, which is formed so as to cover the insulating layer 11, the wiring layer 12a and the wiring layer 12b. The first solder resist 13 can prevent contact between wirings on the wiring layer 12a and the wiring layer 12b. The minimum film thickness of the solder resist layer 13 is a film thickness that can cover the wiring layer 12a and the wiring layer 12b and the maximum film thickness of the solder resist layer 13 is a film thickness that does not cause a crack due to strain at manufacturing and usage of the semiconductor device 1. The film thickness of the solder resist layer 13 is, for example, in the range of 25 to 70 μm. The solder resist layer 13 is opened so as to expose parts of the wiring layers 12a, 12b.

The first solder resist 13 includes a first elastomer 15 for relaxing internal stress. The first elastomer 15 is a polymer with an average particle size of 5 to 15 μm that disperses in the solder resist layer 13. The first elastomer 15 has a glass transition point that is equal to or lower than a temperature for curing the sealing resin 30 (for example, not higher than 150° C.), is softened at a temperature that is equal to or higher than the glass transition point and exhibits an adhesive property. Since the solder resist layer 13 also exists between the insulating layer 11 and the semiconductor element 20, the solder resist layer 13 needs to have an ability to bear the strain caused by thermal deformation of the insulating layer 11 and the semiconductor element 20 in the resin sealing step. The first elastomer 15 acts to relax the internal stress caused by the deformation and prevent occurrence of the crack on the solder resist layer 13 and removal of the solder resist layer 13 from the insulating layer 11. However, the first elastomer 15 softens at the glass transition point or higher and thus, is easy to adhere to other members. Consequently, the first elastomer 15 exposed from a surface of the solder resist layer 13 becomes hard to be removed when contacting the mold 41 and the mold 42 in the resin sealing step, thereby contributing to the lowering of manufacturing efficiency. Compositions of the solder resist layer 13 and the first elastomer 15 may be compositions of well known solder resists and elastomer.

The second solder resist 14 is an insulating film which is formed so as to cover the first solder resist 13 and located on a surface of the wiring substrate 10. Like the first solder resist 13, the second solder resist 14 is opened to expose parts of the wiring layers 12a, 12b. An electrode pad is formed on each of the openings. The second solder resist 14 prevents electrical short-circuit from occurring at parts other than the electrode pads.

The second solder resist 14 includes no first elastomer 15. Since the second solder resist 14 includes no first elastomer 15, at temperatures of the glass transition point of the first elastomer 15 or higher, a surface of the second solder resist 14 has a smaller adhesive strength to the mold 41 and the mold 42 than a surface of the first solder resist 13. For this reason, a resin component in the second solder resist 14 is hard to adhere to the mold 41 and the mold 42 due to heat generated in the resin sealing step. Even when heat (temperatures of the glass transition point of the first elastomer 15 or higher) is applied in the resin sealing step, the second solder resist 14 is advantageously hard to adhere to the mold 41 and the mold 42. It is preferred that composition of the second solder resist 14 is the same as that of the first solder resist 13 except for the first elastomer 15. Namely, it is preferred that the resin component of the first solder resist and the resin component of the second solder resist are formed by same material. It is especially preferred that the resin components of the first solder resist 13 and the second solder resist 14 are the same as each other because it makes interlayer bonding between the both solder resists stronger, resulting in that the solder resists are hardly removed even at application of the above-mentioned internal stress due to deformation. Here, the resin component of the solder resist denotes a base material of the solder resist, not including elastomer.

The minimum film thickness of the solder resist layer 14 is a film thickness that can cover the first elastomer 15 exposed from the surface of the first solder resist 13 and the maximum film thickness of the solder resist layer 14 is a film thickness that does not cause a crack due to strain at manufacturing and usage of the semiconductor device 1. That is, the second solder resist 14 prevents the first elastomer 15 from adhering to the mold 41 and the mold 42 without allowing the first elastomer 15 exposed from the surface of the first solder resist 13 to be exposed from the surface of the second solder resist 14. The film thickness of the solder resist layer 14 is, for example, in the range of 1 to 10 μm, preferably, 1 to 2 μm.

FIG. 5 is a sectional view showing a state in which the wiring substrate 10 in FIG. 4 is in contact with the mold 41 in the resin sealing step. Referring to FIG. 5, since the second solder resist 14 does not include the first elastomer 15 which softens due to heat and adheres to the mold 41, the second solder resist 14 can be easily removed from the mold 41. Although not shown in FIG. 5, similarly, the second solder resist 14 can be easily removed from the mold 42. Accordingly, in the wiring substrate 10 in the first embodiment of the present invention, since the second solder resist 14 can be easily removed from the mold 41 and the mold 42, the manufacturing efficiency of the semiconductor device 1 can be improved. The second solder resist 14 may include no elastomer or may include elastomer which is harder to soften due to heat than the first elastomer 15.

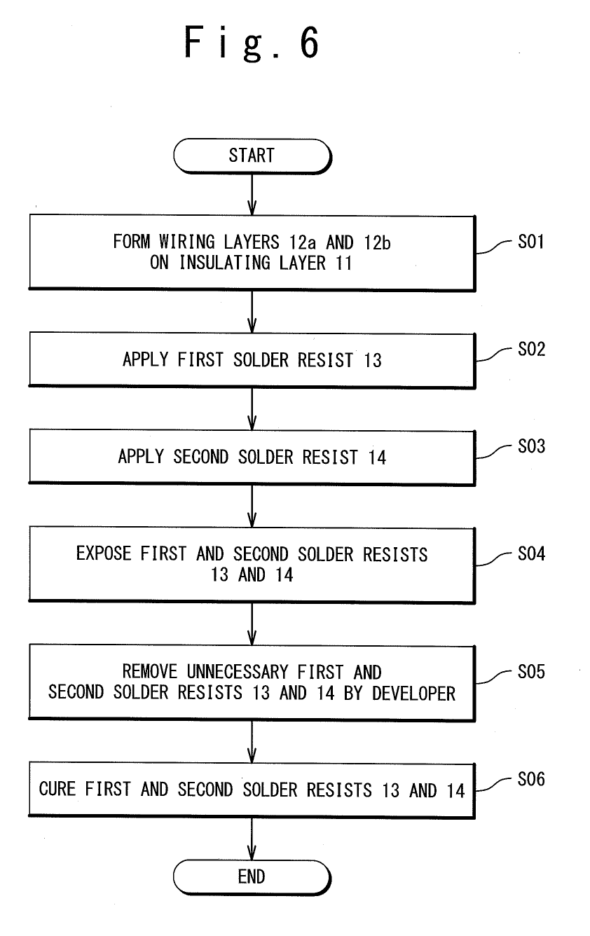

FIG. 6 is a flow chart showing a method of manufacturing the wiring substrate 10 according to the first embodiment of the present invention. Referring to FIG. 6, the method of manufacturing the wiring substrate 10 according to the first embodiment of the present invention will be described.

The wiring layer 12a and the wiring layer 12b are formed on the insulating layer 11 having insulating properties such as a glass epoxy substrate or a glass composite substrate. The wiring layer 12a and the wiring layer 12b may be formed according to any of well known wiring pattern forming methods such as etching (Step S01). In the manufacturing step in Step S01, the insulating layer 11 on which the wiring layer 12a and the wiring layer 12b are formed may be procured. In this case, Step S01 is replaced with a step of providing the insulating layer on which the wiring layer 12a and the wiring layer 12b are formed.

The first solder resist 13 including the first elastomer 15 is applied to cover the insulating layer 11, the wiring layer 12a and the wiring layer 12b. Examples of the application method include a spray method, a screen printing method, a roller coating method and a curtain coater method. The first solder resist 13 is applied so as to have the thickness after curing in the range of 25 to 70 μm. The first solder resist 13 may be applied once or plural times. The applied first solder resist 13 is dried by thermal treatment. For example, the first solder resist 13 is dried under 60 to 100° C. for 1 to 30 minutes (Step S02).

Next, the second solder resist 14 including no first elastomer 15 is applied. The second solder resist 14 is applied in a similar manner as the first solder resist 13. The second solder resist 14 is applied so as to have the thickness after curing in the range of 1 to 10 μm, preferably, 1 to 2 μm. Further, like the first solder resist 13, the second solder resist 14 is dried by thermal treatment (Step S03). Although the first solder resist 13 and the second solder resist 14 are separately dried in the flow chart in FIG. 6, the first solder resist 13 and the second solder resist 14 may be simultaneously dried.

The first solder resist layer 13 and the second solder resist 14 are exposed through a mask based on a predetermined resist pattern of the first solder resist 13 and the second solder resist 14. Exposure is performed, for example, by light such as ultraviolet rays. Alternatively, the first solder resist 13 and the second solder resist 14 are exposed as drawn based on the predetermined resist pattern by laser (Step S04). The first solder resist layer 13 and the second solder resist 14 each may be either a negative resist, solubility to a developer of which decreases when exposed, resulting in that an exposed portion remains after development, or a positive resist, solubility to a developer of which increases when exposed, resulting in that the exposed portion is removed.

Unnecessary portions of the exposed first solder resist 13 and the second solder resist 14 are removed by use of a developer (Step S05). Thereby, by flip chip connection or wire bonding connection, and bonding of an external terminal such as a solder ball, electrode pads formed of parts of the wiring layers 12a, 12b are formed.

The first solder resist 13 and the second solder resist 14 are cured by further heating and ultraviolet irradiation. For example, the first solder resist 13 and the second solder resist 14 are heated at 100 to 200° C. for 30 to 60 minutes (Step S06). The first solder resist 13 and the second solder resist 14 are cured by only heating, only ultraviolet irradiation or combination of heating and ultraviolet irradiation depending on material for the solder resists. In the method of combining heating and ultraviolet irradiation, for example, the solder resists are cured by heating and further irradiated with ultraviolet rays. Whereby, even when an uncured portion of the solder resists remains after heating, the solder resists can be completely cured by subsequent ultraviolet irradiation.

In the flow chart in FIG. 6, although the first solder resist 13 and the second solder resist 14 are simultaneously exposed and developed, the solder resists can be separately exposed and developed. When the first solder resist 13 is applied plural times, application and drying, and exposure and development can be repeatedly performed.

Finally, the electrode pads exposed from the first solder resist 13 and the second solder resist 14 are subjected to surface treatment. Specifically, the electrode pads are subjected to nickel coating, gold plating, solder coating, fluxing, anti-rust treatment or the like.

A manufacturing process by which the wiring substrate 10 manufactured according to the flow chart in FIG. 6 becomes the semiconductor device 1 will be described referring to FIG. 2. The semiconductor element 20 is connected to the wiring substrate 10 by wire bonding connection (not shown) or flip chip connection (not shown). The mold 41 and the mold 42 enclose the wiring substrate 10 on which the semiconductor element 20 is mounted to form a cavity filled with the sealing resin 30. The sealing resin 30 in a high-temperature fluid state is filled into the cavity formed by the mold 41 and the mold 42. The mold 41 and the mold 42 are heated to about 150 to 200° C., thereby curing the sealing resin 30 filled to the cavity (FIG. 2). The semiconductor device 1 including the cured sealing resin 30 is taken out of the mold 41 and the mold 42. In the step of taking the semiconductor device 1 out of the mold 41 and the mold 42, since the wiring substrate 10 is hard to adhere to the mold 41 and the mold 42, the semiconductor device 1 can be easily taken out.

In the first embodiment of the present invention, since the second solder resist layer 14 including no first elastomer that softens due to heat is formed on the surface of the wiring substrate 10, the surface does not have the adhesive property even when heated and is easy to separate from the mold 41 and the mold 42. Therefore, the semiconductor device 1 of the present embodiment using the wiring substrate 10 can be easily taken out of the mold 41 and the mold 42 after the resin sealing step. That is, since the wiring substrate 10 of the present embodiment does not spend much time in removal from the mold 41 and the mold 42 and cleaning of the first elastomer 15 adhered to the mold 41 and the mold 42, the manufacturing efficiency of the semiconductor device 1 can be improved. Further, since dirt is hard to adhere to the mold 41 and the mold 42, dirt can be prevented from transferring from the mold 41 and the mold 42 to the wiring substrate 10, and an assembly failure that the electrode pads on the wiring substrate 10 is not attached to the solder ball can be also prevented. In addition, since the wiring substrate 10 of the present embodiment is easily removed from the mold 41 and the mold 42, static electricity can be prevented from occurring at removal, thereby avoiding a functional failure of the semiconductor device 1 (semiconductor element 20).

### Second Embodiment

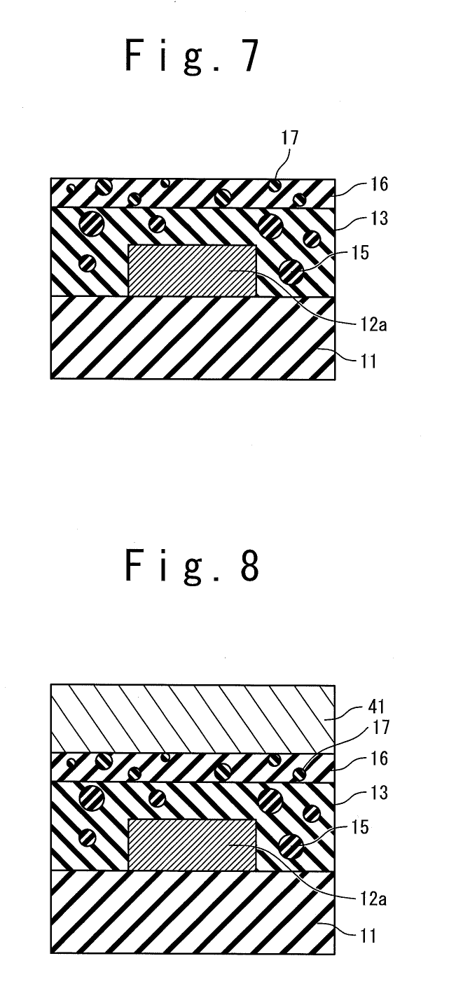

A second embodiment of the present invention will be described. The second embodiment of the present invention is different from the first embodiment in that the second embodiment uses a second solder resist 16 for the wiring substrate 10. Since the other configuration is the same as that of the first embodiment, the same components are represented by the same reference numerals and description thereof is omitted. FIG. 7 is a partial sectional view showing the wiring substrate 10 according to the second embodiment of the present invention. FIG. 7 is an enlarged view of the portion A shown in FIG. 3, and a cross section of the wiring substrate 10 is similar to that shown in FIG. 1. Further, the resin sealing step of the semiconductor device 1 according to the second embodiment of the present invention is similar to that shown in FIG. 2.

Referring to FIG. 7, the wiring substrate 10 according to the second embodiment of the present invention includes the insulating layer 11, the wiring layer 12a, the first solder resist 13 and the second solder resist 16. Although not shown, as in the first embodiment, the wiring layer 12b is formed on the insulating layer 11 on an opposite side to the wiring layer 12a.

The second solder resist 16 is an insulating film which is formed so as to cover the first solder resist 13 and located on a surface of the wiring substrate 10. Like the first solder resist 13, the second solder resist 16 is opened so as to expose parts of the wiring layers 12a, 12b. The second solder resist 16 prevents electrical short-circuit from occurring at parts other than the exposed parts of the wiring layers 12a, 12b.

The second solder resist 16 in the second embodiment includes a second elastomer 17. Like the first elastomer 15, the second elastomer 17 is a polymer that disperses in the second solder resist 16 and relaxes internal stress. The second elastomer 17 has a glass transition point which is equal to or lower than a temperature that cures the sealing resin 30 (for example, 150° C. or lower), and softens and exhibits the adhesive property at the glass transition point or higher. Compositions of the second solder resist 16 and the second elastomer 17 may be compositions of well known solder resists and elastomer and may be the same as compositions of the first solder resist 13 and the first elastomer 15, respectively.

The second solder resist 16 has the second elastomer 17 that softens due to heat and exhibits the adhesive property, and the second solder resist 16 is advantageously harder to adhere to the mold 41 and the mold 42 than the first solder resist 13 in the resin sealing step. That is, the second solder resist 16 has a property that the surface thereof has smaller adhesive strength than that of the first solder resist 13 at the glass transition point of the first elastomer 15 (temperature at which the surface of the first solder resist 13 starts to exhibit the adhesive property). Describing in more detail, in the second solder resist 16, a surface area of the second elastomer 17 as an adhesive component exposed from the surface of the second solder resist 16 is smaller than a surface area of the first elastomer 15 as an adhesive component exposed from the surface of the first solder resist 13, or the second elastomer 17 has a higher glass transition point than the first elastomer 15.

The amount of the second elastomer 17 in the second solder resist 16 and the average particle size of the second elastomer 17 to realize the relation that the surface area of the second elastomer 17 exposed from the surface of the second solder resist 16 is smaller than that of the first elastomer exposed from the surface of the first solder resist 13 will be described. A percent by weight of the second elastomer 17 to the resin component of the second solder resist 16 is smaller than that of the first elastomer 15 to the resin component of the first solder resist 13. Since the amount of the second elastomer 17 in the second solder resist 16 is small, the surface area of the second elastomer 17 as the adhesive component exposed from the surface of the second solder resist 16 can be reduced. Further, the average particle size of the second elastomer 17 is smaller than that of the first elastomer 15. For example, the average particle size is 5 μm or smaller. In the second solder resist 16, in addition to reduce the amount of the second elastomer 17, the surface area of the second elastomer 17 exposed from the surface of the second solder resist 16 can be further reduced by making the average particle size of the second elastomer 17 smaller than that of the first elastomer 15.

The film thickness of the second solder resist 16 in the second embodiment will be described. The minimum film thickness of the second solder resist 16 is made larger than the average particle size of the second elastomer 17. It is desired that the second solder resist 16 has a film thickness of 5 μm or larger. On the other hand, the film thickness of the second solder resist 16 is made smaller than that of the first solder resist 13. The reason is that when the minimum film thickness of the second solder resist 16 is smaller than the average particle size of the second elastomer 17, the second elastomer 17 exposed from the surface of the second solder resist 16 increases and becomes easy to adhere to the mold 41 and the mold 42. Further, although the second solder resist 16 can relax internal stress, since it is preferred that the relaxation of internal stress is performed mainly by the first solder resist 13 including the first elastomer 15, the maximum film thickness of the second solder resist 16 preferably does not exceed that of the first solder resist 13. Furthermore, it is preferred that the film thickness of the second solder resist 16 is smaller than twice as large as the average particle size of the second elastomer 17. In this case, the layer thickness of the second solder resist 16 is smaller than the height of the piled second elastomer 17 (twice as large as the average particle size), it can be prevented that particles of the second elastomer 17 are piled in the second solder resist 16. When the molds 41, 42 are crimped onto the second solder resist 16 in this state, particles of the second elastomer 17 is not piled. As a result, pressure is equally applied to the second elastomer 17 in the second solder resist 16 and therefore, it can be prevented that a part of the second elastomer 17 adheres to the molds 41, 42.

FIG. 8 is a sectional view showing a state in which the wiring substrate 10 shown in FIG. 7 is in contact with the mold 41 in the resin sealing step. Referring to FIG. 8, since the area of the surface of the second elastomer 17 that contacts the mold 41 is small, the second solder resist 16 can be easily removed from the mold 41. Although not shown in FIG. 8, the second solder resist 16 can likewise be easily removed from the mold 42.

The method of manufacturing the wiring substrate 10 according to the second embodiment of the present invention is similar to the method of manufacturing the wiring substrate 10 according to the first embodiment as shown in the flow chart in FIG. 6. Referring to FIG. 6, steps that are different from those in the first embodiment will be described. In Step S03, the second solder resist 16 including the second elastomer 17 in place of the second solder resist 14 is applied. The application method of the second solder resist 16 is similar to that of the first solder resist 13. The second solder resist 16 is applied so as to have a film thickness after curing that is equal to or larger than the average particle size of the second elastomer 17 and to be thinner than the first solder resist 13, desirably, to be less than twice as large as the average particle size of the second elastomer 17. Further, like the first solder resist 13, the second solder resist 16 is dried by thermal treatment. The other steps are similar to those in the first embodiment.

The second solder resist 16 is formed on the wiring substrate 10 in the second embodiment of the present invention, and the surface area of the second elastomer 17 exposed from the second solder resist 16 is small. Accordingly, advantageously, the wiring substrate 10 has a small adhesive property when heated and thus, is hard to adhere. That is, as in the first embodiment, the semiconductor device 1 using the wiring substrate 10 can be easily taken out of the mold 41 and the mold 42 after the resin sealing step, thereby improving the manufacturing efficiency. In addition, since the second elastomer 17 in the second solder resist 16 can relax internal stress, the wiring substrate 10 in the second embodiment of the present invention can improve the effect of suppressing occurrence of cracks.

### Third Embodiment

A third embodiment of the present invention will be described. The third embodiment of the present invention is obtained by combining the first embodiment with the second embodiment. Therefore, the same components as those in the first embodiment and the second embodiment are represented by the same reference numerals and description thereof is omitted.

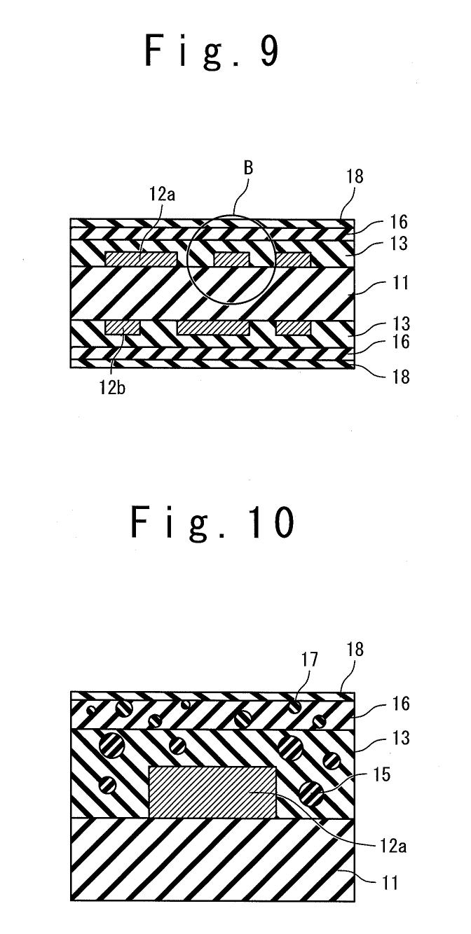

FIG. 9 is a partial sectional view showing the wiring substrate 10 according to the third embodiment of the present invention. A cross section of the semiconductor device 1 according to the third embodiment of the present invention is similar to that of the wiring substrate 10 in FIG. 1 except that the three layers of solder resists are provided in the wiring substrate 10. The resin sealing step is similar to that in FIG. 2 except that the three layers of solder resists are provided. Referring to FIG. 9, the wiring substrate 10 in the third embodiment of the present invention includes the insulating layer 11, the wiring layer 12a, the wiring layer 12b, the first solder resist 13, the second solder resist 16 and the third solder resist 18. The wiring substrate 10 may be a multi-layer substrate having four or more wiring layers 12a or wiring layers 12b. The insulating layer 11, the wiring layer 12a, the wiring layer 12b, the first solder resist 13 and the second solder resist 16 in this embodiment are similar to those in the second embodiment.

FIG. 10 is an enlarged view of the portion B shown in FIG. 9. Referring to FIG. 10, the third solder resist 18 will be described. The third solder resist 18 is an insulting film that is formed so as to cover the second solder resist 16 and located on a surface of the wiring substrate 10. Like the first solder resist 13 and the second solder resist 16, the third solder resist 18 prevents electrical contact and electrical short-circuit from occurring at parts other than the exposed portions of the wiring layers 12a, 12b.

The solder resist 18 does not include an elastomer similar to the first elastomer 15 and the second elastomer 17. Accordingly, since the third solder resist 18 does not include any adhesive component like the second solder resist 14 in the first embodiment, the third solder resist 18 is advantageously hard to adhere to the mold 41 and the mold 42 due to heat generated in the resin sealing step. Further, since the average particle size of the second elastomer 17 included in the second solder resist 16 is smaller than that of the first elastomer 15, the film thickness of the third solder resist 18 can be made smaller than the film thickness of the second solder resist 14 in the first embodiment, that is, to be equal to or smaller than 1 μm.

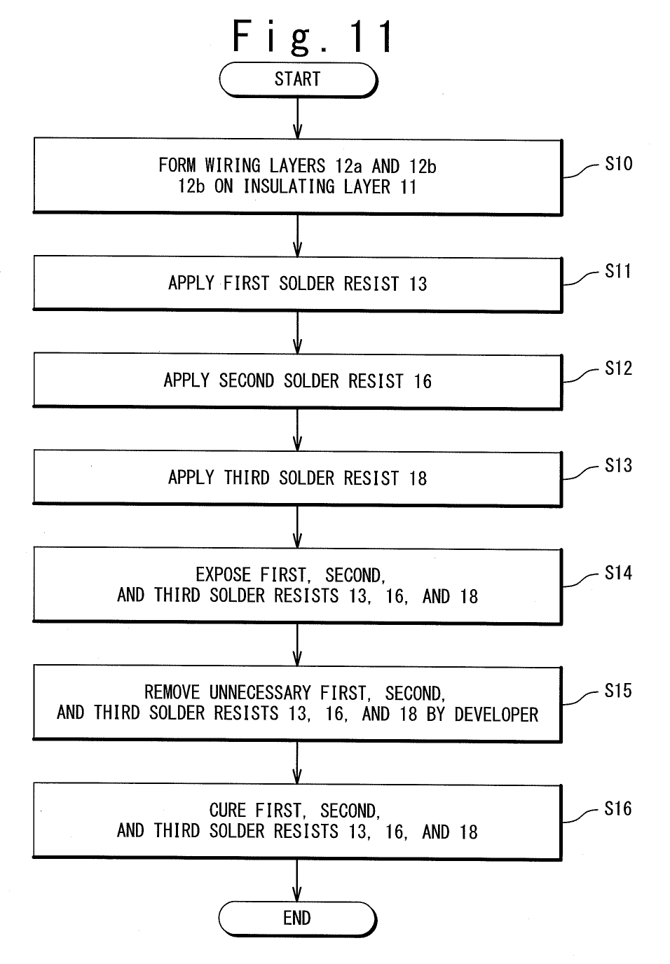

FIG. 11 is a flow chart showing a method of manufacturing the wiring substrate 10 according to the third embodiment of the present invention. Referring to FIG. 11, the method of manufacturing the wiring substrate 10 according to the third embodiment of the present invention will be described.

The wiring layer 12a and the wiring layer 12b are formed on the insulating layer 11 having insulating properties such as a glass epoxy substrate or a glass composite substrate (Step S10).

The first solder resist 13 including the first elastomer 15 is applied so as to cover the insulating layer 11, the wiring layer 12a and the wiring layer 12b. Examples of applying method include a spray method, a screen printing method, a roller coating method and a curtain coater method. The first solder resist 13 is applied so as to have a thickness after curing in the range of 25 to 70 μm. The applied first solder resist 13 is dried by thermal treatment. For example, the applied first solder resist 13 is dried under 60 to 100° C. for 1 to 30 minutes (Step S11).

The second solder resist 16 including the second elastomer 17 is applied. The application method of the second solder resist 16 is similar to that of the first solder resist 13. The second solder resist 16 is applied so as to have a film thickness after curing of 5 μm or larger and to be thinner than the first solder resist 13. Preferably, the film thickness after curing is made smaller than twice as large as the average particle size of the second elastomer 17. Further, like the first solder resist 13, the second solder resist 16 is dried by thermal treatment (Step S12).

A third solder resist 18 including no elastomer is applied. The application method is similar to that of the first solder resist 13 and the second solder resist 16. The third solder resist 18 is applied so as to have a film thickness after curing of 1 μm or less. Like the first solder resist 13 and the second solder resist 16, the third solder resist 18 is dried by thermal treatment (Step S13).

The first solder resist 13, the second solder resist 16 and the third solder resist 18 are exposed, for example, by a light including ultraviolet rays through a mask or to be drawn by a laser, based on a predetermined resist pattern (Step S14). The first solder resist 13, the second solder resist 16 and the third solder resist 18 may be either the negative type or the positive type.

Unnecessary portions of the exposed first solder resist 13, the second solder resist 16 and the third solder resist 18 are removed by use of a developer (Step S15). Thereby, by flip chip connection or wire bonding connection, and bonding of an external terminal such as a solder ball, electrode pads formed of parts of the wiring layers 12a, 12b are formed.

The first solder resist 13, the second solder resist 16 and the third solder resist 18 are cured by at least either heating or ultraviolet irradiation. For example, these are heated under 100 to 200° C. for 30 to 60 minutes (Step S16).

Since a manufacturing process by which the wiring substrate 10 manufactured according to the flow chart in FIG. 11 becomes the semiconductor device 1 is similar to that in the first and second embodiments, description thereof is omitted.

The third embodiment of the present invention can be obtained by combining the first and second embodiments of the present invention with each other consistently. In the third embodiment, the third solder resist 18, from which the first elastomer 15 and the second elastomer 17 as adhesive components that soften due to heat are not exposed, is formed on the wiring substrate 10. Consequently, the surface of the wiring substrate 10 advantageously has no adhesive property even when heated and is hard to adhere. Further, the third solder resist 18 can be made thinner than the second solder resist 14 in the first embodiment since the average particle size of the second elastomer 17 included in the second solder resist 16 is smaller than that of the first elastomer 15. As in the first and second embodiments, the semiconductor device 1 using the wiring substrate 10 in the third embodiment of the present invention can be easily taken out of the mold 41 and the mold 42 after the resin sealing step, the manufacturing efficiency of the semiconductor device 1 can be improved.

The first to third embodiments have been described. Although only one semiconductor element 20 is shown in FIGS. 1 to 5, FIGS. 7 to 10, a plurality of semiconductor elements may be mounted on the wiring substrate 10. Further, the semiconductor element 20 is mounted on only one side of the wiring substrate 10, the semiconductor element 20 may be mounted on both sides of the wiring substrate 10. In this case, the sealing resin is formed on both sides of the wiring substrate 10.

The semiconductor device 1 is manufactured by using the wiring substrate 10 according to any of the first to third embodiments of the present invention. Although the resin sealing step of the semiconductor device 1 has been described in this specification, the other steps relating to manufacturing of the semiconductor device 1 can be performed according to any method well-known to those skilled in the art.

### Fourth Embodiment

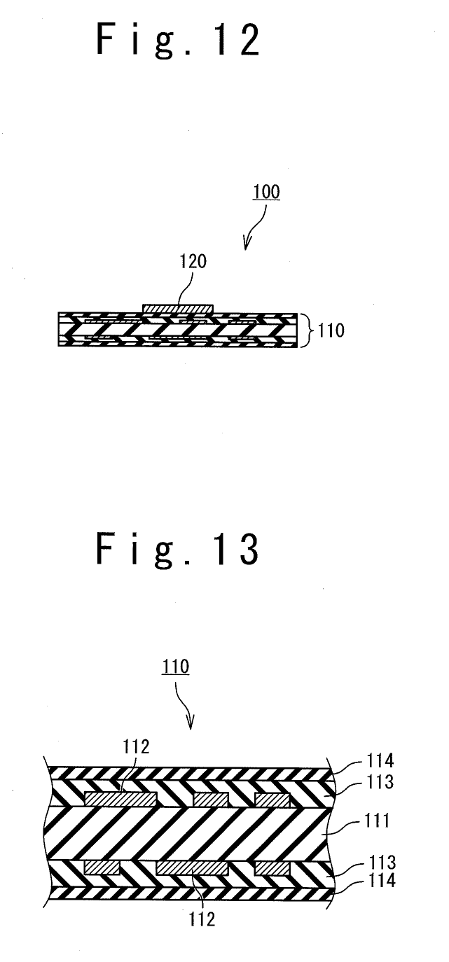

The configuration of the wiring substrates 10 according to the first to third embodiments of the present invention can be applied to a mounting board. FIG. 12 is a sectional view of a semiconductor device 100 according to a fourth embodiment. Referring to FIG. 12, the semiconductor device 100 includes a mounting board 110 and a semiconductor package 120.

FIG. 13 is a partial enlarged view of the mounting board 110 shown in FIG. 12. Referring to FIG. 13, the mounting board 110 includes an insulating layer 111, a wiring layer 112, a first solder resist 113 and a second solder resist 114. A configuration of each component of the mounting board 110 is similar to that of the wiring substrate 10. That is, the insulating layer 111 is similar to the insulating layer 11, the wiring layer 112 is similar to the wiring layer 12a and the wiring layer 12b, the first solder resist 113 is similar to the first solder resist 13 and the second solder resist 114 is similar to the second solder resist 14 or the second solder resist 16. Further, the second solder resist 114 may be a two-layer structure including the second solder resist 16 and the third solder resist 18.

Referring to FIG. 12, the semiconductor package 120 is a semiconductor package manufactured by any well known method, and the semiconductor devices 1 according to the first to third embodiments of the present invention are exemplified. The semiconductor device 100 can be manufactured by any method known to those skilled in the art. As described above, the electronic device of the present invention can be applied to a wiring substrate (package substrate, mounting board), and a semiconductor device in which the semiconductor element is mounted on a wiring substrate (package substrate, mounting board).

What is claimed is:

1. An electronic device comprising:
an insulating layer;
a wiring layer formed on a surface of the insulating layer;
a first solder resist formed to cover the insulating layer and the wiring layer and including a particle of a first elastomer; and
a second solder resist formed to cover a surface of the first solder resist,
wherein a surface of the second solder resist has smaller adhesive strength than the surface of the second solder resist at a glass transition point of the first elastomer.

2. The electronic device according to claim 1, wherein the second solder resist includes a particle of a second elastomer, and
a surface area of the second elastomer exposed from the surface of the second solder resist is smaller than a surface area of the first elastomer exposed from the surface of the first solder resist.

3. The electronic device according to claim 2, wherein a percent by weight of the second elastomer to a resin component of the second solder resist is smaller than a percent by weight of the first elastomer to a resin component of the first solder resist.

4. The electronic device according to claim 3, wherein the second elastomer is smaller than the first elastomer in an average particle size.

5. The electronic device according to claim 1, wherein a resin component of the first solder resist and a resin component of the second solder resist are formed by same material.

6. The electronic device according to claim 5, further comprising:
a third solder resist formed to cover the surface of the second solder resist and including no elastomer particle formed by same material to the particle of the first elastomer or the particle of the second elastomer.

7. The electronic device according to claim 1, wherein the second solder resist is thinner than the first solder resist in a film thickness.

8. The electronic device according to claim 1, wherein a semiconductor chip is mounted on the second solder resist, and
the semiconductor chip is sealed by a sealing resin.

9. The electronic device according to claim 1, wherein the second solder resist includes no elastomer.

10. A manufacturing method of a electronic device comprising:
applying a first solder resist including a particle of a first elastomer to cover an insulating layer and a wiring layer formed on a surface of the insulating layer;
applying a second solder resist to cover a surface of the first solder resist;
exposing the first solder resist and the second solder resist based on a resist pattern;
removing unnecessary portions of the first solder resist and the second solder resist; and
curing the first solder resist and the second solder resist,
wherein a surface of the second solder resist has smaller adhesive strength than the surface of the second solder resist at a glass transition point of the first elastomer.

11. The manufacturing method of the electronic device according to claim 10, wherein the curing is performed by at least one of heating and an irradiation of a ultraviolet ray.

12. The manufacturing method of the electronic device according to claim 10, wherein the applying the second solder resist comprises:
applying the second solder resist to be thinner than the first solder resist.

13. The manufacturing method of the electronic device according to claim 12, wherein a percent by weight of the second elastomer to a resin component of the second solder resist is smaller than a percent by weight of the first elastomer to a resin component of the first solder resist.

14. The manufacturing method of the electronic device according to claim 13, wherein the second elastomer is smaller than the first elastomer in an average particle size.

15. The manufacturing method of the electronic device according to claim 10, wherein a resin component of the first solder resist and a resin component of the second solder resist are formed by same material.

16. The manufacturing method of the electronic device according to claim 10, wherein the applying the second solder resist comprises:
applying a solder resist including a second elastomer to cover the surface of the first solder resist; and
applying a solder resist including no elastomer particle formed by same material to the particle of the first elastomer or the particle of the second elastomer.

17. The manufacturing method of the electronic device according to claim 10, further comprising:
mounting a semiconductor chip on the second solder resist after the curing;
depositing a mold on the second solder resist to cover the semiconductor chip;
sealing the semiconductor chip by injecting a sealing resin into a space between the semiconductor chip and the mold; and
demolding the sealing resin and the mold after the sealing.

18. The manufacturing method of the electronic device according to claim 10, further comprising:
providing the insulating layer, the wiring layer is formed on a surface thereof, before the applying the first solder resist.

19. The manufacturing method of the electronic device according to claim 10, further comprising:
forming the wiring layer on a surface of the insulating layer before the applying the first solder resist.
